(19) United States
(12) Patent Application Publication
(10) Pub. No.: US 2006/0016965 A1
(43) Pub. Date: Jan. 26, 2006

(54) Optics elements configured for light sensing applications and related methods of manufacturing

(75) Inventors: Joseph S. Stam, Holland, MI (US); Steven J. Gager, Holland, MI (US)

Correspondence Address: BRIAN J. REES;GENTEX CORPORATION, 600 NORTH CENTENNIAL STREET, ZEELAND, MI, 49464, US

(73) Assignee: Gentex Corporation

(21) Appl. No.: 11/185,145

(22) Filed: Jul. 20, 2005

Related U.S. Application Data
(60) Provisional application No. 60/590,736, filed on Jul. 23, 2004.

(51) Int. Cl. H01J 3/14

(52) U.S. Cl. 250/216; 250/226

(57) ABSTRACT

The present invention relates to improved optical elements configured for light sensing applications and to systems comprising the improved optical elements.

### CROSS REFERENCE TO RELATED APPLICATIONS

This application claims priority under 35 U.S.C. §119(e) to U.S. Provisional patent application Ser. No. 60/590,736, to Stam et al., filed Jul. 23, 2004.

### BACKGROUND OF THE INVENTION

Consumer electronics devices, such as, digital cameras, digital video recorders, video telephones and the like are becoming commonplace. These devices along with a host of residential, commercial, industrial and vehicular vision systems have popularized CCD and CMOS based image sensors. Known systems designed to automatically control vehicle exterior lights, for example, utilize a forward looking digital imaging system to acquire images of the scene generally in front of the controlled vehicle and analyze images to detect headlights of oncoming vehicles and taillights of leading vehicles. Security cameras are prevalent throughout residential, commercial and industrial facilities, as well as, associated vehicle parking areas.

Cost effective lenses for such imaging systems are typically molded from a transparent plastic material such as polycarbonate. A large advantage of plastic lenses is that mechanical features to attach the lens or register it's position with respect to other components may be molded integral with the active optical surfaces of the lens. However, in such a configuration the non-active surfaces may need to be made opaque to prevent light from being transmitted through them and onto the sensor. This can be accomplished by providing a separate opaque plastic part with holes which only expose the optically active regions of the transparent lens to light. The use of a separate component has several drawbacks: it creates additional cost, creates additional manufacturing complexity, adds the risk of scratching the active optical components during assembly, and may create part-to-part inconsistencies due to variability in the separate component and its registration to the transparent lens element.

What is needed are methods of forming an opaque region on an optics element to prevent light from transmitting through certain regions of the element. Preferably, the methods provide a high degree of accuracy and consistency.

### SUMMARY OF THE INVENTION

The present invention provides optics elements configured for light sensing applications that comprise laser formed at least partially opaque regions and methods of manufacture. In at least one embodiment, an optical element configured for light sensing is molded of an organic material and at least one at least partially opaque area is then formed preferably using a laser. In at least one embodiment, an optics element is molded of a polycarbonate material having a dual lens structure and a Nd:YAG laser formed opaque region surrounding the dual lens optically active structure.

It should be understood that any laser and any organic materials may be employed as long as an absorption band of the organic material and the laser light emissions are selected such that the desired at least partially opaque region is formed when the organic material is exposed to a laser. It should also be understood that additional materials may be added to the organic material to result in an at least partially opaque region that is spectrally more or less transmissive as desired.

In at least one embodiment, various embodiments of the present invention are integrated within vehicular, residential, commercial, industrial and consumer electronic devices. In at least one related embodiment, the various integrated systems are configured to share components for improved operation and, or, to lower associated costs.

Other advantages of the present invention will become apparent when reading the following detail description in light of the figures, examples and appended claims.

### BRIEF DESCRIPTION OF THE FIGURES

FIG. 1 depicts a controlled vehicle relative to the taillights of a leading vehicle and the headlights of an oncoming vehicle;

FIG. 2 depicts a controlled vehicle;

FIG. 3a depicts a perspective view of an interior rearview mirror assembly;

FIG. 3b depicts a second perspective view of the mirror assembly of FIG. 3;

FIG. 4 depicts a perspective view of an exploded stationary assembly;

FIG. 5 depicts a digital electronic camera;

FIGS. 6a-c depicts various views of various optical elements.

### DETAILED DESCRIPTION OF THE INVENTION

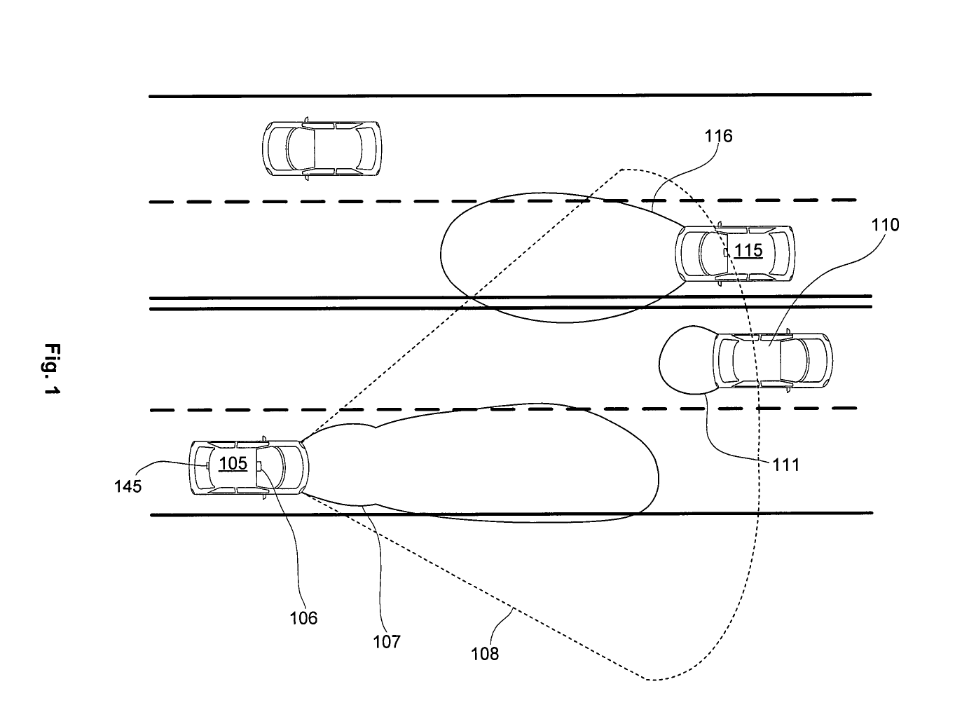

Referring initially to FIG. 1, for illustrative purposes, an automatic vehicle equipment control system 106 is shown to be installed within a controlled vehicle 105. Although the control system 106 is depicted to be integral with the interior rearview mirror assembly, it should be understood that the control system, or any of the individual components thereof, may be mounted in any suitable location within the interior, or on the exterior, of the controlled vehicle 105. The term “controlled vehicle” is used herein with reference to a vehicle comprising an automatic vehicle exterior light control system. Suitable locations for mounting the associated image sensor are those locations that provide an unobstructed view of the scene generally forward of the controlled vehicle 105 and allow for detection of headlights 116 of oncoming vehicles 115 and taillights 111 of leading vehicles 110 within the glare zone 108 associated with the controlled vehicle.

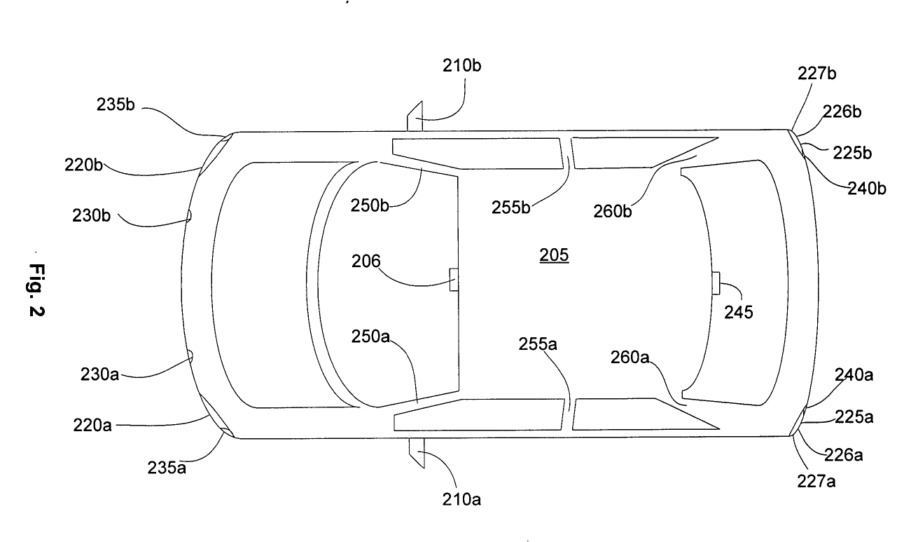

FIG. 2 depicts a controlled vehicle 205 comprising an interior rearview mirror assembly 206 incorporating an automatic vehicle exterior light control system. The processing and control system functions to send configuration data to the imager, receive image data from the imager, to process the images and to generate exterior light control signals. Detailed descriptions of such automatic vehicle exterior light control systems are contained in commonly assigned U.S. Pat. Nos. 5,837,994, 5,990,469, 6,008,486, 6,130,448, 6,130,421, 6,049,171, 6,465,963, 6,403,942, 6,587,573, 6,611,610, 6,621,616, 6,631,316 and U.S. patent application Ser. Nos. 10/208,142, 09/799,310, 60/404,879, 60/394,583, 10/235,476, 10/783,431, 10/777,468 and 09/800,460; the disclosures of which are incorporated herein in their entireties by reference. The controlled vehicle is also depicted to include a driver's side outside rearview mirror assembly 210a, a passenger's side outside rearview mirror assembly 210b, a center high mounted stop light (CHMSL) 245, A-pillars 250a, 250b, B-pillars 255a, 255b and C-pillars 260a, 260b; it should be understood that any of these locations may provide alternate locations for an image sensor, image sensors or related processing and, or, control components. It should be understood that any, or all, of the rearview mirrors may be automatic dimming electro-optic mirrors. The controlled vehicle is depicted to include a host of exterior lights including headlights 220a, 220b, foil weather lights 230a, 230b, front turn indicator/hazard lights 235a, 235b, tail lights 225a, 225b, rear turn indicator lights 226a, 226b, rear hazard lights 227a, 227b and backup lights 240a, 240b. It should be understood that additional exterior lights may be provided, such as, separate low beam and high beam headlights, integrated lights that comprise multipurpose lighting, etc. It should also be understood that any of the exterior lights may be provided with positioners (not shown) to adjust the associated primary optical axis of the given exterior light. It should be understood that the controlled vehicle of FIG. 2 is generally for illustrative purposes and that suitable automatic vehicle exterior light control systems, such as those disclosed in the patents and patent applications incorporated herein by reference, may be employed along with other features described herein and within disclosures incorporated herein by reference.

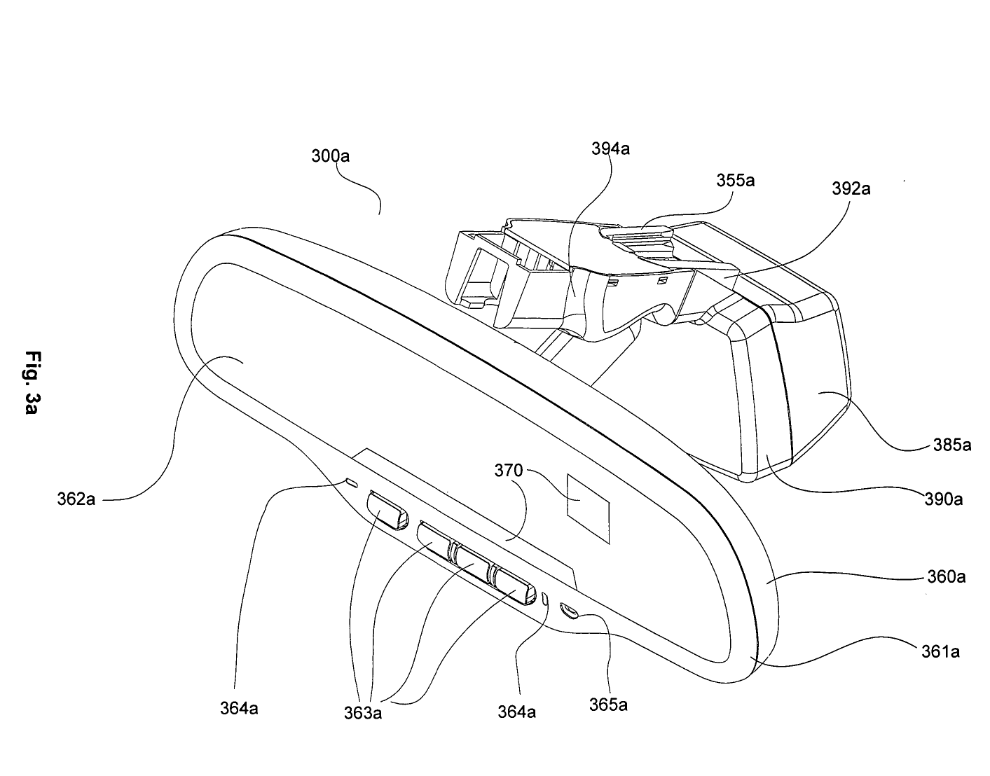

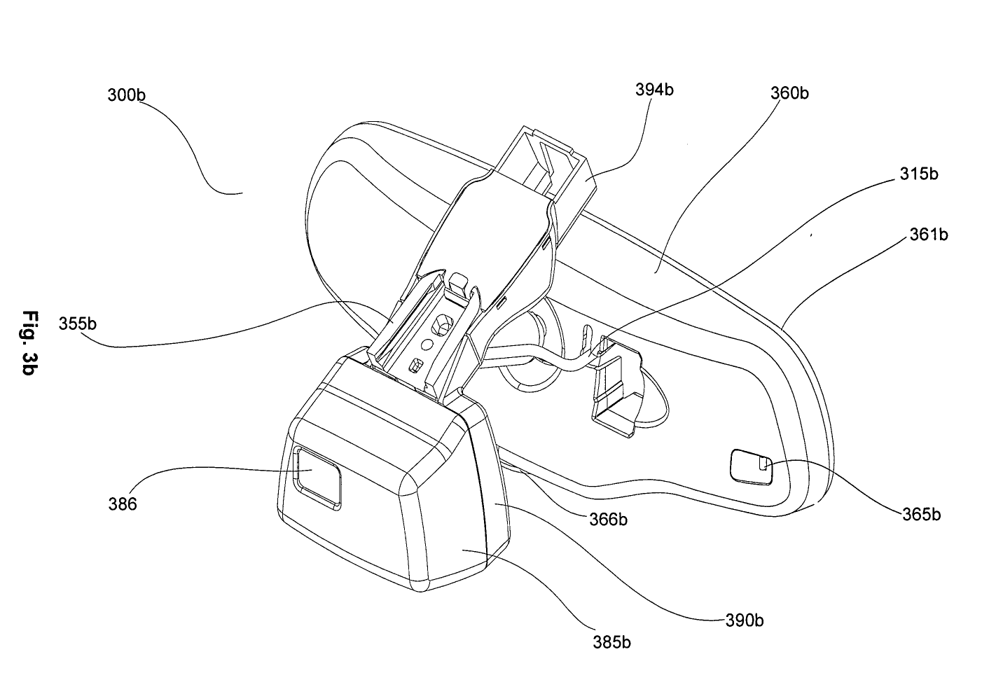

Turning now to FIGS. 3a and 3b, an embodiment of an interior rearview mirror assembly 300a, 300b is shown. The mirror assembly includes a stationary accessory assembly enclosed within a front housing 385a, 385b and a rear housing 390a, 390b. The front housing comprises an aperture 386b defining an image sensor visual opening. The stationary accessory assembly along with a rearview mirror are carried by an attachment member 355a, 355b. The rearview mirror comprises a mirror housing 360a, 360b, a bezel 361a, 361b and a mirror element 362a. A wire cover 394a, 394b is included to conceal related wiring 315b. The rearview mirror assembly 300a, 300b also incorporates an ambient light sensor 365b, at least one microphone 366b, a glare light sensor 365a, operator interfaces 363a, indicators 364a and at least one information display 370.

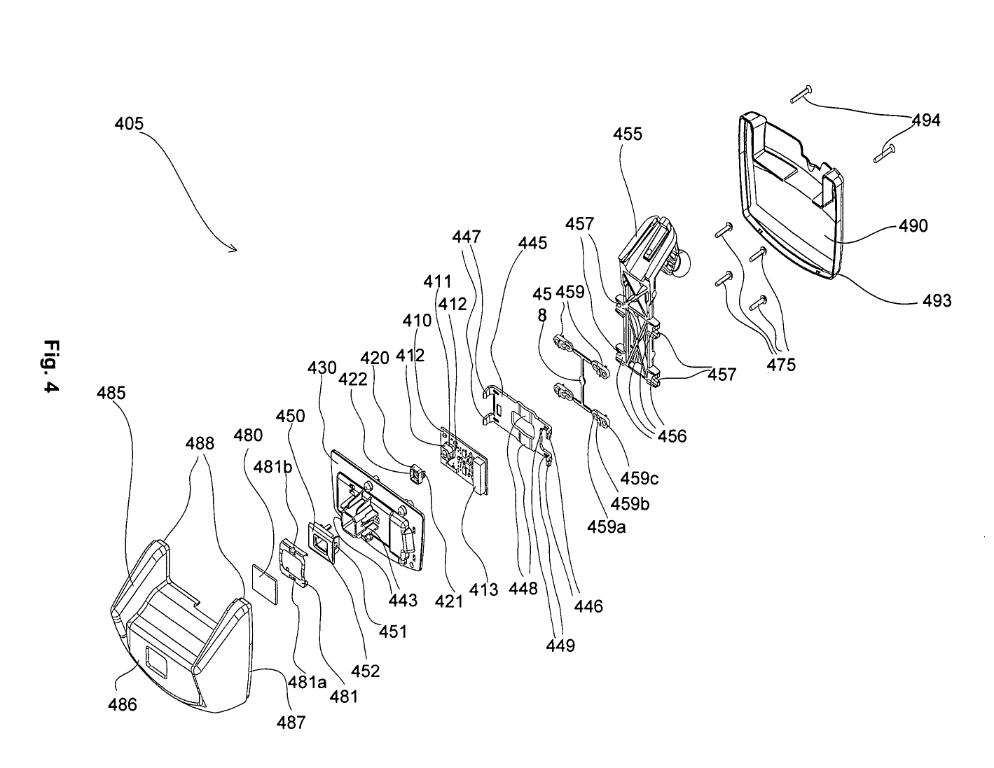

Turning now to FIG. 4, there is shown an exploded, perspective, view of an accessory and rearview mirror mount assembly 405. In a preferred embodiment, the accessory and rearview mirror mount assembly provides a rigid structure for mounting a repositionably mounted interior rearview mirror along with a precisely aligned image sensor either stationarily mounted as described in more detail within commonly assigned U.S. patent application Ser. No. 10/783,273 (7606) or automatically repositioning as described in commonly assigned U.S. patent application Ser. No. 10/645,801, both of which are hereby incorporated in their entireties herein by reference. A preferred accessory and rearview mirror mount assembly facilitates ease of assembly as well as provides for repeatable, reliable and precise alignment of the related components. In at least one embodiment, the associated imager is used for automatic exterior vehicle light control for which precision alignment of the image sensor is preferred. It should be understood that the present invention has broad application to light sensing optics generally, in addition to, automotive and consumer electronics applications.

Imager board 410 is provided with an image sensor with lens 411. In a preferred embodiment, the imager board will also include an image sensor control logic and timing circuit, communication line drivers and wire harness receptacle 413. Optionally, the imager board may comprise a processor for receiving and, at least partially, processing images obtained from the image sensor. In a preferred embodiment, the image sensor and at least one other device selected from the group comprising; 1) an image sensor control logic; 2) an A/D converter; 3) a low voltage differential signal line driver; 4) a temperature sensor; 5) a control output; 6) a voltage regulator; 7) a second image sensor; 8) a microprocessor; 9) a moisture sensor and 10) a compass are integrated in a common ASIC, most preferably on a common silicon wafer. In at least one embodiment, the image sensor with lens 411 includes lens cover snap portions 412 for engaging a lens cover 420 snap clips 421. The lens cover has an aperture 422 for alignment with the optical axis of the image sensor and lens. Various suitable optical systems, such as those depicted and described in commonly assigned U.S. Pat. Nos. 5,990,469; 6,008,486; 6,130,421; 6,130,448; 6,049,171; and 6,403,942 and U.S. Patent Application Ser. No. 60/495,906 (2880); the disclosures of which are incorporated herein in their entireties by reference; may be employed. It should be understood that optics in accordance with the present invention may obviate the need for a lens cover 420 as described in detail herein. It should be understood that the lens cover snap portions, the lens optical cover and snap clips may be eliminated with use of optical elements in accordance with the present invention. In at least one embodiment, the “lens cover” is formed on a molded organic material optics element using a laser as described in detail herein.

An imager board wiring harness (not shown) is preferably provided with plugs on either end thereof. The imager board is preferably provided with a male receptacle 413 for receiving one of the plugs of the imager board wiring harness (not shown).

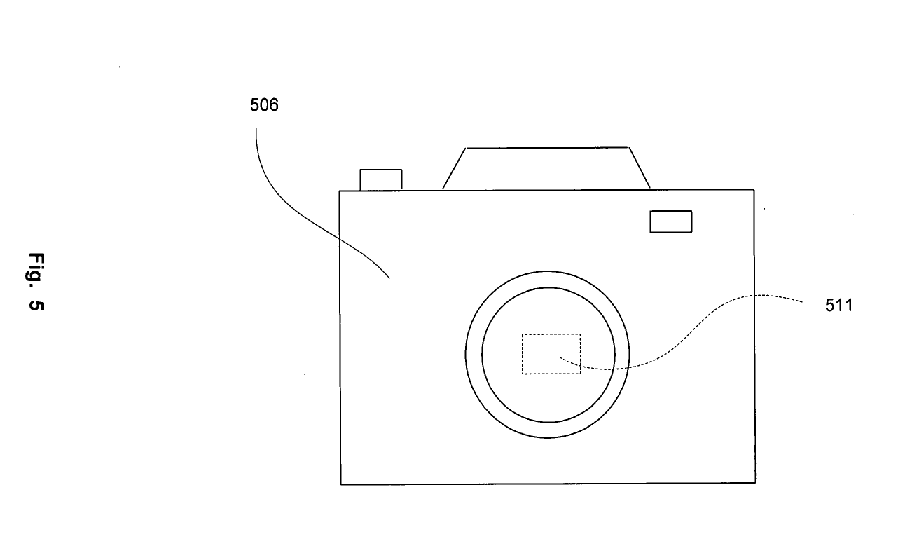

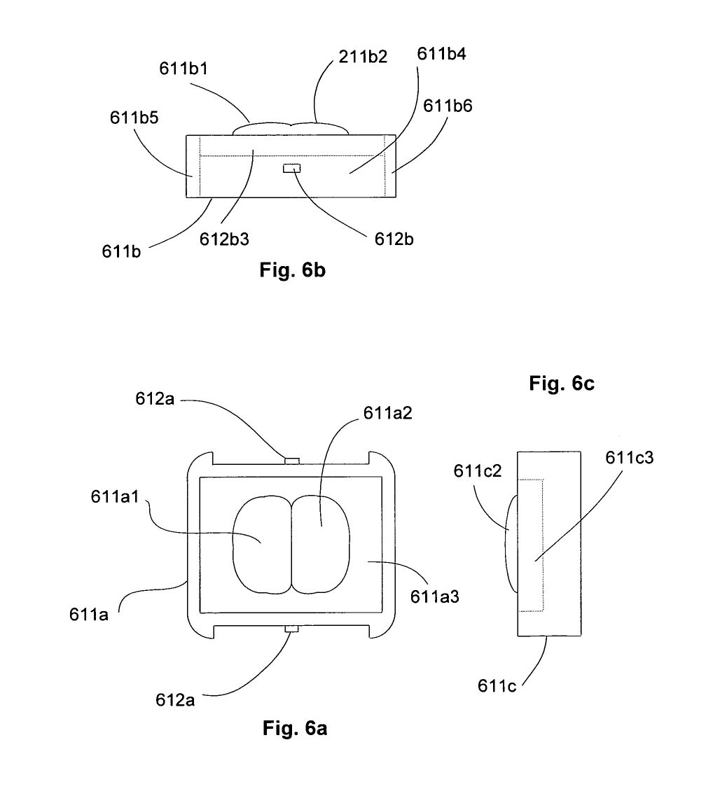

FIG. 5 depicts a profile view of a digital camera 506 having an imager with lens 511 in accordance with the present invention. It should be understood that optics in accordance with the present invention may be incorporated into a host of assemblies included, but not limited to, light sensing, image acquisition, moisture sensing, rear-vision systems, lane departure detection systems, adaptive cruse control systems, occupancy detection systems, security systems, vision systems, color measurement systems, head lamp control systems, variable reflectance rearview mirror control systems, digital video recorders and digital cameras. A given optics may be secured in a fixed position relative an associated image sensor or may be attached via a repositioning means as known in the art. Turning now to FIGS. 6a-6c, an optical element 611a is depicted as comprising a first lens 611a1, a second lens 611a2, an at least partially opaque area 211a3 and lens cover snap portions 612a for engaging a lens cover. It should be understood that the optical element may comprise one or more lenses depending upon the actual application. The at least partially opaque area 211a3 may comprise multiple discontinuous areas one continuous area.

In at least one embodiment, an optical element is provided that is molded of at least an organic material such as polycarbonate, polyarylate, polymacrylate, SAN, SMMA and PMMA and acrylic (i.e. use of an absorbing material on a surface of acrylic has been found to assist in forming an opaque area using a laser). In a related embodiment, an at least partially opaque area is provided by laser abrading the molded organic material. It should be understood that various materials may be used within the molded optical element to produce a color other than black when exposed to a laser that emits light rays defining a band of energy within a corresponding absorption band of the molded optical element. Laser abrading an at least partially opaque area mask provides for precise alignment of the mask relative the lens. Alternate mask configurations are taught in commonly assigned U.S. Pat. Nos. 6,130,421, 6,611,610 and 6,587,573, the disclosures of which are incorporated herein in their entireties by reference. Commonly assigned U.S. patent application Ser. Nos. 10/777,468 (2265), 10/783,131 (7106) and 10/783,273 (7606), the disclosures of which are incorporated in their entireties herein, disclose various systems in which an optical element may be advantageously employed.

Profile views of an optical element are depicted in FIGS. 6b and 6c. In at least one embodiment, the lens cover snap portions 612b, a recessed portion 611b4 and slide portions 611b5, 611b6 cooperate to secure a lens cover to the optical element [not in this embodiment]. In a related embodiment, the lens cover is configured to surround a first lens 611b1 and a second lens 611b2. As further depicted, the depth of the at least partially opaque area 611b3 as well as, in addition to or in lieu of the length and, or width 611c3 may be variable throughout any given at least partially opaque area. It should be understood that in at least one embodiment, an area associated with at least one at least partially opaque area may have an associated optical element profile configured such that depth of the at least partially opaque area substantially coincides with at least a portion of a width and, or, length of the at least partially opaque area. This configuration facilitates visual inspection of the resulting laser abraded optical element.

In at least one embodiment, an optical element 611c comprises a second lens 611c2 and an at least partially opaque area 611c3 with a transmissivity that is a function of at least a depth of the at least partially opaque area. In at least one embodiment, a substantially entirely opaque area defines an optically active aperture. When used in combination with at least one light sensor the optical element with aperture, at least in part, defines a desired field of view.

In the preferred embodiment, the laser marked opaque area is formed using a Nd:YAG laser shortly after molding. The laser energy from the Nd:YAG laser effectively “burns” the plastic material thus marking the part and forming the opaque region. After the lens has been removed from the mold, it is fixtured under a laser. Commonly available laser marking systems provide highly precise control to steer the laser beam to mark or oblate an area. The system is programmed to move the beam in a pattern to form the opaque region in the shape desired. If more precision is desired a vision system can be utilized to locate the lens and shift the marking pattern accordingly.

The above description is considered that of the preferred embodiments only. While the embodiments shown herein relate to an imaging system for vehicle headlamp control and a digital camera, it should be understood that these techniques may be employed for a variety of light sensing and imaging systems, both for vehicular and non vehicular applications. Many plastic lenses require an opaque region to be formed surrounding the optically active lens surfaces. It should also be understood that different types of plastics, different types of lasers, and different means of locating or fixturing the lens component may be used effectively. Modifications of the invention will occur to those skilled in the art and to those who make or use the invention.

Therefore, it is understood that the embodiments shown in the drawings and described above are merely for illustrative purposes and not intended to limit the scope of the invention, which is defined by the following claims as interpreted according to the principles of patent law, including the doctrine of equivalents.

What is claimed is:

1. An apparatus, comprising:
an optical element material defining an optical element configured to sense light comprising a dual lens structure comprising an optically active area surrounded by an at least partially opaque mask, wherein said at least partially opaque mask is formed in said optical element using a laser having a primary emission wavelength substantially equal to a primary absorption wavelength said optical element material.

2. An apparatus as in claim 1 configured within at least one of the group comprising: light sensing, image acquisition, a moisture sensing system, a rear-vision system, a lane departure detection system, an adaptive cruse control system, an occupancy detection system, a security system, a vision system, a color measurement system, a head lamp control system, a variable reflectance rearview mirror control system, a digital video recorder and a digital camera.

3. An apparatus as in claim 1 said optical element material comprising an organic material.

4. An apparatus as in claim 1 said optical element material comprising at least one selected from the group comprising: polycarbonate, polymacrylate and acrylic.

5. An apparatus as in claim 1 further comprising at least one light sensor, wherein said optical element with aperture at least partially defines a field of view of said at least one light sensor.

6. An apparatus as in claim 1 wherein said at least partially opaque mask is at least partially formed using a Nd:YAG laser.

7. An apparatus as in claim 1 further comprising an image sensor, wherein said optical element with aperture at least partially defines a field of view of said image sensor.

8. An apparatus, comprising:
at least one light sensor; and
an optical element material defining an optical element configured to sense light comprising a dual lens structure comprising an optically active area surrounded by an at least partially opaque mask, wherein said at least partially opaque mask is formed in said optical element and said optical element with aperture at least partially defines a field of view of said at least one light sensor.

9. An apparatus as in claim 8 configured within at least one of the group comprising: light sensing, image acquisition, a moisture sensing system, a rear-vision system, a lane departure detection system, an adaptive cruse control system, an occupancy detection system, a security system, a vision system, a color measurement system, a head lamp control system, a variable reflectance rearview mirror control system, a digital video recorder and a digital camera.

10. An apparatus as in claim 8 said optical element material comprising an organic material.

11. An apparatus as in claim 8 said optical element material comprising at least one selected from the group comprising: polycarbonate, polymacrylate and acrylic.

12. An apparatus as in claim 8 wherein said at least partially opaque mask is formed in said optical element using a laser having a primary emission wavelength substantially equal to a primary absorption wavelength said optical element material.

13. An apparatus as in claim 8 wherein said at least partially opaque mask is at least partially formed using a Nd:YAG laser.

14. An apparatus as in claim 8 further comprising an image sensor, wherein said optical element with aperture at least partially defines a field of view of said image sensor.

15. An apparatus, comprising:
an optical element material defining an optical element configured to sense light comprising a lens structure comprising an optically active area at least partially surrounded by an at least partially opaque area, wherein said at least partially opaque area is formed in said optical element using a laser, said optical element is configured to substantially block light from passing through at least a portion of an area outside an optically active area.

16. An apparatus as in claim 15 configured within at least one of the group comprising: light sensing, image acquisition, a moisture sensing system, a rear-vision system, a lane departure detection system, an adaptive cruse control system, an occupancy detection system, a security system, a vision system, a color measurement system, a head lamp control system, a variable reflectance rearview mirror control system, a digital video recorder and a digital camera.

17. An apparatus as in claim 15 said optical element material comprising an organic material.

18. An apparatus as in claim 15 said optical element material comprising at least one selected from the group comprising: polycarbonate, polymacrylate and acrylic.

19. An apparatus as in claim 15 further comprising at least one light sensor, wherein said optical element with aperture at least partially defines a field of view of said at least one light sensor.

20. An apparatus as in claim 15 wherein said at least partially opaque mask is at least partially formed using a Nd:YAG laser.

21. An apparatus as in claim 15 further comprising an image sensor, wherein said optical element with aperture at least partially defines a field of view of said image sensor.
